(19) United States
(12) Patent Application Publication
(10) Pub. No.: US 2024/0317579 A1
(43) Pub. Date: Sep. 26, 2024

(54) MEMS SENSOR, AND METHOD FOR MANUFACTURING MEMS SENSOR

(71) Applicant: ROHM CO., LTD., Kyoto (JP)

(72) Inventors: Daisuke KAMINISHI, Kyoto-shi (JP); Martin Wilfried HELLER, Kyoto-shi (JP); Toma FUJITA, Kyoto-shi (JP)

(73) Assignee: ROHM CO., LTD., Kyoto (JP)

(21) Appl. No.: 18/676,090

(22) Filed: May 28, 2024

Related U.S. Application Data
(63) Continuation of application No. PCT/JP2022/040778, filed on Oct. 31, 2022.

(30) Foreign Application Priority Data
Nov. 30, 2021 (JP) 2021-194815

(51) Int. Cl. B81C 1/00; B81B 7/00; G01P 15/125

(52) U.S. Cl. CPC B81C 1/00269; B81B 7/0006; G01P 15/125; B81B 2201/0235; B81B 2203/0353; B81B 2203/04; B81C 2201/013; B81C 2201/0159; B81C 2201/0176; B81C 2203/037

(57) ABSTRACT

A MEMS sensor includes a bond portion in which a metal structure in a device substrate and a metal laminate are eutectically bonded. The bond portion bonds the device substrate and a lid substrate. The metal laminate is located on a main surface of the lid substrate and facing an exposed portion in the metal structure. The metal laminate includes a first metal and a second metal different from the first metal.

### BACKGROUND

### Technical Field

The disclosure relates to a micro-electromechanical systems (MEMS) sensor and a method for manufacturing a MEMS sensor.

### Background Art

U.S. Pat. No. 8,319,254 B describes a MEMS sensor including a device substrate and a lid substrate bonded with glass frit. A MEMS electrode on the device substrate is sealed with such bonding. Another known bonding technique that may be used to bond the device substrate and the lid substrate is diffusion bonding.

### BRIEF DESCRIPTION OF THE DRAWINGS

FIG. 1 is a schematic plan view of a MEMS sensor according to an embodiment of the disclosure;

FIG. 2 is a cross-sectional view taken along line II-II in FIG. 1;

FIG. 3 is an enlarged view of area III in FIG. 2;

FIG. 4 is a cross-sectional view of a device substrate assembly in one of manufacturing processes;

FIG. 5 is a cross-sectional view of the device substrate assembly in a process subsequent to the process in FIG. 4;

FIG. 6 is a cross-sectional view of the device substrate assembly in a process subsequent to the process shown in FIG. 5;

FIG. 7 is a cross-sectional view of the device substrate assembly in a process subsequent to the process shown in FIG. 6;

FIG. 8 is a cross-sectional view of the device substrate assembly in a process subsequent to the process shown in FIG. 7;

FIG. 9 is a cross-sectional view of the device-substrate assembly in a process subsequent to the process shown in FIG. 8;

FIG. 10 is a cross-sectional view of the device substrate assembly in a process subsequent to the process shown in FIG. 9;

FIG. 11 is a cross-sectional view of the device substrate assembly in a process subsequent to the process shown in FIG. 10;

FIG. 12 is a cross-sectional view of the device substrate assembly in a process subsequent to the process shown in FIG. 11;

FIG. 13 is a cross-sectional view of a lid substrate assembly in one of manufacturing processes;

FIG. 14 is a cross-sectional view of the lid substrate assembly in a process subsequent to the process shown in FIG. 13;

FIG. 15 is a cross-sectional view of the device substrate assembly in a process subsequent to the process shown in FIG. 14; and

FIG. 16 is a cross-sectional view of the device substrate assembly in a process subsequent to the process shown in FIG. 15;

### DETAILED DESCRIPTION

An embodiment of the disclosure will be described below with reference to the drawings.

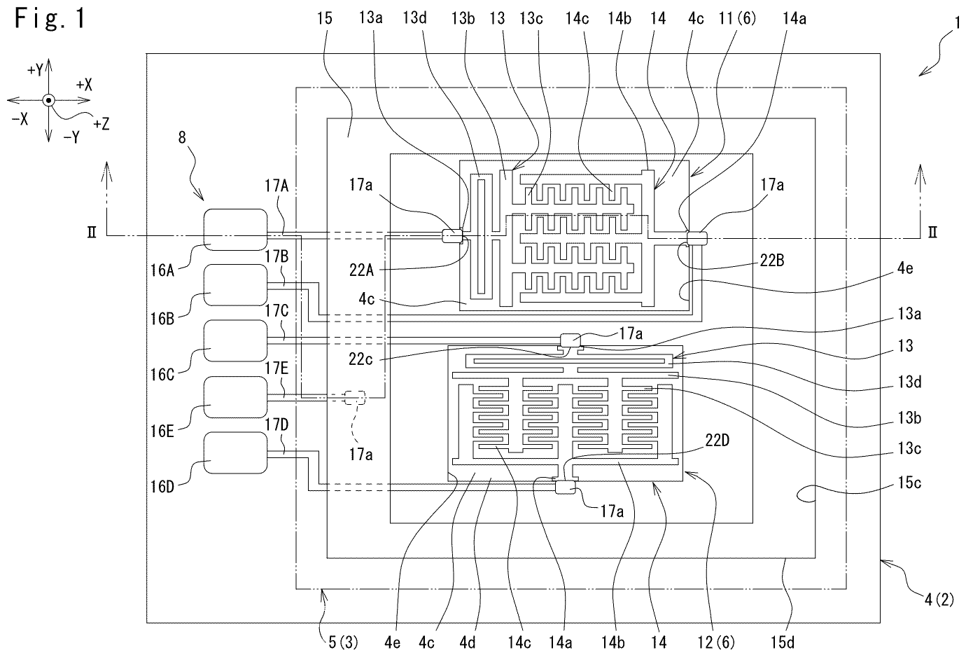

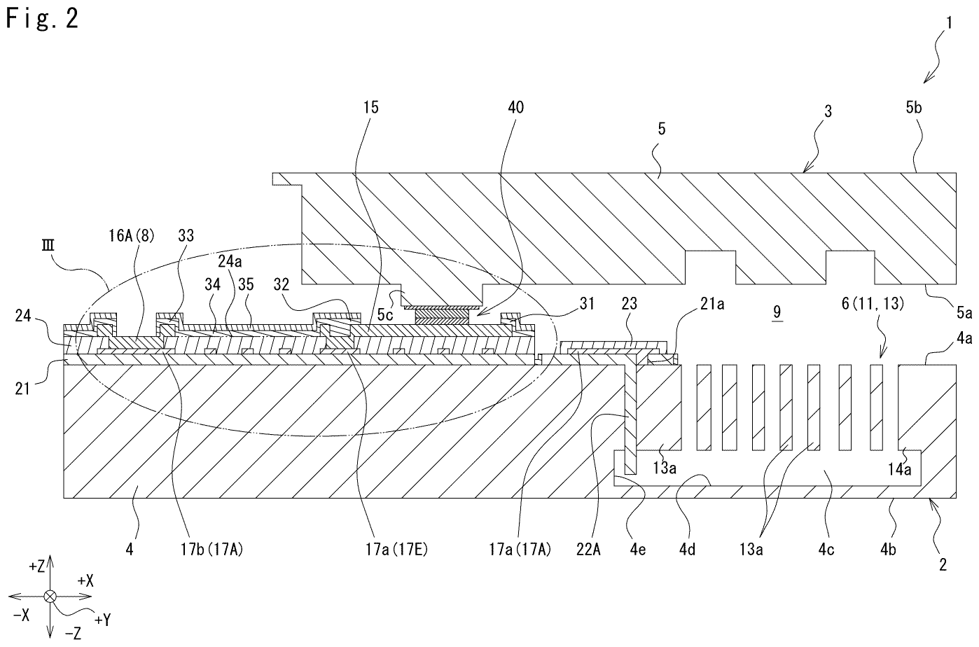

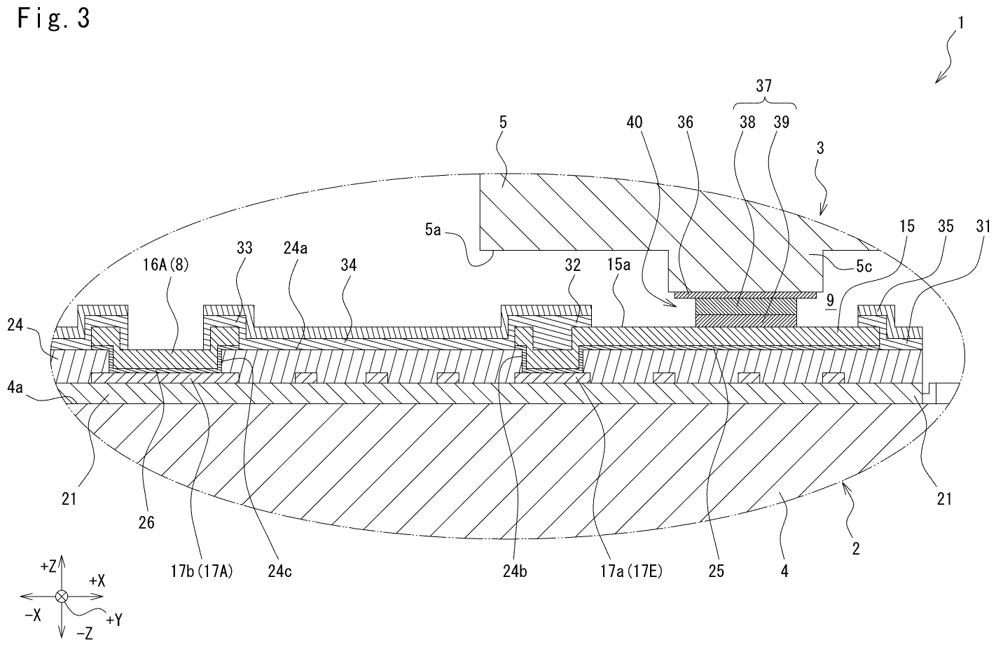

FIG. 1 is a schematic plan view of a micro-electromechanical systems (MEMS) sensor 1 according to an embodiment of the disclosure. FIG. 2 is a cross-sectional view taken along line II-II in FIG. 1. FIG. 3 is an enlarged view of area III in FIG. 2. The MEMS sensor 1 according to the present embodiment is a capacitance accelerator sensor.

The overall structure of the MEMS sensor 1 will be described first.

With reference to FIGS. 1 to 3, the MEMS sensor 1 includes a device substrate assembly (first substrate assembly) 2 and a lid substrate assembly (second substrate assembly) 3. The device substrate assembly 2 includes a device substrate (first semiconductor substrate) 4. The lid substrate assembly 3 includes a lid substrate (second semiconductor substrate) 5. FIG. 1 shows the lid substrate 5 as a transparent member.

The device substrate 4 receives MEMS electrodes 6, which are sensing electrodes in a capacitance accelerator sensor device. The device substrate 4 further receives a pad unit 8 including four electrode pads 16A to 16D to receive electric signals from the MEMS electrodes 6.

The lid substrate 5 faces the device substrate 4 and covers the MEMS electrodes 6. As described in detail later, the device substrate 4 and the lid substrate 5 are connected at a bond portion 40 to have the MEMS electrodes 6 sealed in a space 9 defined between the device substrate 4 and the lid substrate 5.

In the present embodiment, the device substrate 4 and the lid substrate 5 are both rectangular in a plan view. The lid substrate 5 is smaller than the device substrate 4 to expose the pad unit 8.

The X-direction, the Y-direction, and the Z-direction may be referred to below. The X-direction is along the front surface of the device substrate 4. The Y-direction is along the front surface of the device substrate 4 and perpendicular to the X-direction. The Z-direction is perpendicular to the X-direction and the Y-direction, or in other words, the thickness direction of the device substrate 4. In FIG. 1, the positive X-direction refers to a rightward direction, the negative X-direction refers to a leftward direction, the positive Y-direction refers to an upward direction, and the negative Y-direction refers to a downward direction. In FIGS. 2 and 3, the positive Z-direction refers to an upward direction, and the negative Z-direction refers to a downward direction.

With reference to FIGS. 1 to 3, in the present embodiment, the device substrate 4 and the lid substrate 5 are electroconductive single crystal silicon substrates with a resistivity of, for example, 1 to 5 Ω·m. The device substrate 4 has a first main surface (a positive Z-direction surface in the present embodiment) 4a, and a second main surface (a negative Z-direction surface in the present embodiment) 4b opposite to the first main surface 4a. The lid substrate 5 has a third main surface (a negative Z-direction surface in the present embodiment) 5a facing the first main surface 4a of the device substrate 4, and a fourth main surface (a positive Z-direction surface in the present embodiment) 5b opposite to the third main surface 5a.

The MEMS electrodes 6 on the device substrate 4 include an X-axis sensor device 11 that detects acceleration in the X-direction, and a Y-axis sensor device 12 that detects acceleration in the Y-direction. The Y-axis sensor device 12 is located apart from the X-axis sensor device 11 in the negative Y-direction. The Y-axis sensor device 12 has the same structure as the X-axis sensor device 11 rotated by 90 degrees in a plan view. The X-axis sensor device 11 is thus described below. The components in the Y-axis sensor device 12 are denoted with the same or similar reference signs in the drawings and will not be described.

The device substrate 4 has internal hollows 4c, in one of which the X-axis sensor device 11 is located adjacent to the first main surface 4a. Each hollow 4c is defined by a bottom wall 4d and a side wall 4e. The X-axis sensor device 11 includes a movable electrode 13 and a fixed electrode 14. The movable electrode 13 and the fixed electrode 14 are supported at connectors 13a and 14a protruding into the hollow 4c from the side wall 4e. The movable electrode 13 and the fixed electrode 14 are supported in a manner floating over the bottom wall 4d of the hollow 4c. More specifically, the X-axis sensor device 11 is a part of the device substrate 4.

The movable electrode 13 includes a base 13b extending from the connector 13a and multiple electrodes 13c extending in the Y-direction from the base 13b in an interdigitated manner. The fixed electrode 14 includes a base 14b extending from the connector 14a and multiple electrodes 14c extending in the Y-direction from the base 14b in an interdigitated manner. The electrodes 13c in the movable electrode 13 and the electrodes 14c in the fixed electrode 14 are alternately arranged in the X-direction. The base 13b in the movable electrode 13 includes a spring 13d that is elastically deformable in the X-direction. The base 14b in the fixed electrode 14 includes no spring. When the MEMS sensor 1 receives acceleration in the X-direction, the spring 13d deforms elastically to move the movable electrode 13 in the X-direction, while leaving the fixed electrode 14 unmoved. Thus, the electrodes 13c in the movable electrode 13 are moved in the X-direction relative to the electrodes 14c in the fixed electrode 14, changing the capacitance between the movable electrode 13 and the fixed electrode 14. This change in the capacitance appears in electric signals.

As shown in FIG. 1 clearly, the device substrate 4 has a seal structure (metal structure) 15 surrounding the MEMS electrodes 6 in a plan view on the first main surface 4a. Although the seal structure 15 is formed from AlCu in the present embodiment, the seal structure 15 may be formed from Al or an Al alloy other than AlCu. More specifically, the seal structure 15 is formed from a metal material including Al (an example of a first metal). In the present embodiment, the seal structure 15 has a rectangular loop shape in a plan view. With also reference to FIGS. 2 and 3, the seal structure 15 includes an exposed portion 15a exposed in the positive Z-direction of the device substrate assembly 2.

With reference to FIGS. 1 to 3, the lid substrate 5 has a protrusion 5c having a loop shape (a rectangular loop in the present embodiment) in a bottom view on the third main surface 5a. The protrusion 5c corresponds to the seal structure 15 on the device substrate 4.

As described in detail later, the exposed portion 15a in the seal structure 15 is bonded to the protrusion 5c in the lid substrate 5 with the bond portion 40. The bond portion 40 bonds the device substrate 4 and the lid substrate 5 to seal the MEMS electrodes 6 in the space 9 defined by the device substrate 4 and the lid substrate 5. The lid substrate 5 and the seal structure 15 are electrically connected with the bond portion 40.

With reference to FIG. 1, the pad unit 8 in the present embodiment includes five electrode pads 16A to 16E. The connectors 13a and 14a in the X-axis sensor device 11, the connectors 13a and 14a in the Y-axis sensor device 12, and the seal structure 15 are electrically connected to the corresponding electrode pads 16A to 16E through the corresponding five metal wires (metal wire layers) 17A to 17E. The electrode pad 16E electrically connected to the seal structure 15 is connected to the ground. The metal wires 17A to 17E each include a first contact 17a at a first end. Each first contact 17a is electrically connected to the corresponding one of the connectors 13a and 14a in the X-axis sensor device 11, the connectors 13a and 14a in the Y-axis sensor device 12, and the seal structure 15. The metal wires 17A to 17E each include a second contact 17b at a second end, or in other words, at the end opposite to the end at which the first contact 17a is located. Each second contact 17b is electrically connected to the corresponding one of the electrode pads 16A to 16E. In the present embodiment, the metal wires 17A to 17E are formed from AlSi.

The structure of the MEMS sensor 1, specifically its cross-sectional structure, will now be described in detail. In the examples described below, FIGS. 2 and 3 are mainly referred to, but the components or the structures shown in FIG. 1 alone may also be referred to.

The device substrate 4 includes a main insulator film 21 on substantially throughout the first main surface 4a, excluding areas with the MEMS electrodes 6. In particular, the main insulator film 21 extends across the connectors 13a and 14a in the MEMS electrodes 6 and the body of the device substrate 4. In the present embodiment, the main insulator film 21 is formed from SiO₂. FIGS. 2 and 3 show the portion of the main insulator film 21 extending across the body of the device substrate 4 and the connector 13a in the movable electrode 13 in the X-axis sensor device 11.

The device substrate 4 has isolation joints 22A to 22D embedded in the first main surface 4a at the boundary between the connectors 13a and 14a in the MEMS electrodes 6 and the body of the device substrate 4. In the present embodiment, the isolation joints 22A to 22D are formed from SiO₂. The isolation joints 22A to 22D electrically separate the connectors 13a and 14a from the body of the device substrate 4. The isolation joints 22A to 22D cross the corresponding connectors 13a and 14a in a plan view. The isolation joints 22A to 22D further cross the corresponding connectors 13a and 14a in the Z-direction. In the present embodiment, the isolation joints 22A to 22D extend into the hollow 4c from the first main surface 4a of the device substrate 4. FIGS. 2 and 3 show the isolation joint 22A that electrically separates the connector 13a in the movable electrode 13 in the X-axis sensor device 11 from the body of the device substrate 4.

The metal wires 17A to 17E are located on the main insulator film 21. In the present embodiment described above, the metal wires 17A to 17E are formed from AlSi, and each include the first contact 17a and the second contact 17b.

The first contact 17a in each of the metal wires 17A to 17D is located on the corresponding one of the connectors 13a and 14a in the MEMS electrodes 6 across the corresponding one of the isolation joints 22A to 22D. The main insulator film 21 has four first contact holes 21a through which the connectors 13a and 14a are exposed. The first contact 17a in each of the metal wires 17A to 17D partially enters the corresponding first contact hole 21a to be electrically connected to the corresponding one of the connectors 13a and 14a. The first contact 17a in each of the metal wires 17A to 17D is covered with an insulator layer 23. In the present embodiment, the insulator layer 23 is formed from tetra ethoxy silane (TEOS). The first contact 17a in the metal wire 17E is located below the seal structure 15. The first contact 17a in the metal wire 17E is electrically connected to the seal structure 15. FIGS. 2 and 3 show the first contact 17a in the metal wire 17A located on the connector 13a in the X-axis sensor device 11 and the first contact 17a in the metal wire 17E located below the seal structure 15.

The second contact 17b in each of the metal wires 17A to 17E is located below the corresponding one of the electrode pads 16A to 16E. As described later, the second contact 17b in each of the metal wires 17A to 17E is electrically connected to the corresponding one of the electrode pads 16A to 16E. FIGS. 2 and 3 show the second contact 17b in the metal wire 17A located below the electrode pad 16A and corresponding to the connector 13a in the X-axis sensor device 11.

An interlayer insulator layer 24 is located on the main insulator film 21 to cover the metal wires 17A to 17E excluding the first contacts 17a in the metal wires 17A to 17D. In the present embodiment, the interlayer insulator layer 24 is formed from TEOS. The interlayer insulator layer 24 has a flattened surface 24a in the upward direction in the drawing, or in other words, has a flattened surface 24a opposite to its surface adjacent to the first main surface 4a of the device substrate 4.

In the present embodiment described above, the seal structure 15 formed from AlCu and having a rectangular loop shape in a plan view is located on the interlayer insulator layer 24. The interlayer insulator layer 24 has one second contact hole 24b through which the first contact 17a in the metal wire 17E is exposed. The seal structure 15 partially enters the second contact hole 24b to be electrically connected to the first contact 17a in the metal wire 17E.

As shown in FIG. 3 alone, a diffusion barrier layer 25 is located between the seal structure 15 and the interlayer insulator layer 24 and between the part of the seal structure 15 entering the second contact hole 24b and the first contact 17a in the metal wire 17E. The diffusion barrier layer 25 in the present embodiment is a Ti/TIN laminate film including a Ti film on the interlayer insulator layer 24 and the first contact 17a in the metal wire 17E and a TiN film laminated on the Ti film.

The interlayer insulator layer 24 has five third contact holes 24c through which the second contacts 17b in the metal wires 17A to 17E are exposed. The electrode pads 16A to 16E in the present embodiment have their large parts entering the corresponding third contact holes 24c. The periphery of each of the electrode pads 16A to 16E is located on the interlayer insulator layer 24 around the corresponding third contact hole 24c. The part of each of the electrode pads 16A to 16E entering the third contact hole 24c is electrically connected to the second contact 17b in the corresponding one of the metal wires 17A to 17E. In the present embodiment, the electrode pads 16A to 16E are formed from AlCu. The electrode pads 16A to 16E may instead be formed from Al or an Al alloy other than AlCu.

As shown in FIG. 3 alone, a first adhesion layer 26 is located between the part of each of the electrode pads 16A to 16E entering the third contact hole 24c and the second contact 17b in the corresponding one of the metal wires 17A to 17E and between each of the electrode pads 16A to 16E and the interlayer insulator layer 24. The first adhesion layer 26 in the present embodiment is a Ti/TiN laminate film including a Ti film on the second contact 17b in each of the metal wires 16A to 16E and the interlayer insulator layer 24, and a TiN film laminated on the Ti film.

The device substrate 4 has an inner-periphery control wall 31 covering an inner periphery 15b (refer to FIG. 1) of the seal structure 15 and an outer-periphery control wall 32 covering an outer periphery 15c (refer to FIG. 1) of the seal structure 15. The inner-periphery control wall 31 and the outer-periphery control wall 32 each include a portion on the interlayer insulator layer 24 and a portion extending from the portion on the interlayer insulator layer 24 along the sides of the seal structure 15 to cover a corner formed with the sides and the apex (in the positive Z-direction surface) of the seal structure 15 to the outer periphery of the apex. The inner-periphery control wall 31 and the outer-periphery control wall 32 define the exposed portion 15a in the seal structure 15.

Barriers 33 cover the outer peripheries of the five electrode pads 16A to 16E. Each barrier 33 includes a portion on the interlayer insulator layer 24 and a portion extending from the portion on the interlayer insulator layer 24 along the sides of the corresponding one of the electrode pads 16A to 16E to cover a corner formed with the sides and the apex (positive Z-direction surface) of the corresponding one of the electrode pads 16A to 16E to the outer periphery of the apex.

In the present embodiment, the outer-periphery control wall 32 and the barrier 33 are connected by an intermediate structure 34 on the interlayer insulator layer 24. In other words, the outer-periphery control wall 32, the barrier 33, and the intermediate structure 34 are integral with one another.

The inner-periphery control wall 31, the outer-periphery control wall 32, the barrier 33, and the intermediate structure 34 include oxide films. In the present embodiment, the inner-periphery control wall 31, the outer-periphery control wall 32, the barrier 33, and the intermediate structure 34 are formed from undoped silicate glass (USG).

A barrier film 35 is located on the surfaces of the inner-periphery control wall 31, the outer-periphery control wall 32, the barrier 33, and the intermediate structure 34. The barrier film 35 functions as a mask to protect the inner-periphery control wall 31, the outer-periphery control wall 32, the barrier 33, and the intermediate structure 34 when etching (described later) is performed to form the seal structure 5 and the electrode pads 16A and 16B, or more specifically, to expose the surfaces of the seal structure 5 and the electrode pads 16A and 16B. Thus, the barrier film 35 is formed from a material resistant to such etching. In the present embodiment, the barrier film 35 is formed from Al. The barrier film 35 may be formed from AlO₂.

The lid substrate 5 has a second adhesion layer 36 at the distal end of the protrusion 5c with a rectangular loop shape on the third main surface 5a. The second adhesion layer 36 is a Ti/TiN laminate film formed from a Ti film on the distal end of the protrusion 5c and a TiN film laminated on the Ti film.

The distal end of the protrusion 5c has a metal laminate 37 with the second adhesion layer 36 between the distal end and the metal laminate 37. More specifically, the metal laminate 37 is located on the portion of the third main surface 5a of the lid substrate 5 facing the seal structure 15. In the present embodiment, the metal laminate 37 includes an Al layer 38 (formed from an example of a first metal) and a Ge layer 39 (formed from an example of a second metal different from the first metal) laminated on the Al layer 38. The metal laminate 37, or in other words, the Al layer 38 and the Ge layer 39, form AlGe eutectic bonding with the seal structure 15 (formed from AlCu as described above) on the device substrate 4, and thus form the bond portion 40 that bonds the device substrate 4 and the lid substrate 5.

In this manner, the bond portion 40 bonding the device substrate 4 and the lid substrate 5 includes AlGe eutectic bonding. The bond portion 40 including AlGe eutectic bonding is formed from a eutectic metal that is a ductile material, and cracks less easily. The bonding width (e.g., the dimension of the bond portion 40 in the X-direction in FIGS. 2 and 3) can be reduced, with the sealing performance retained for the MEMS electrodes 6. The MSMS sensor 1 thus achieves size reduction. As described later, the bond portion 40 including AlGe eutectic bonding is formed by, for example, lithography or etching instead of printing, and thus can reduce particles. When the bond portion 40 including AlGe eutectic bonding is formed, the bonding surfaces between the device substrate 4 and the lid substrate 5, more specifically, the top surface of the exposed portion 15a in the seal structure 15 serving as a bonding surface of the device substrate 4 and the top surface of the protrusion 15a serving as a bonding surface of the lid substrate 5, can have less flatness being intended than when the bond portion 40 is formed by diffusion bonding. More specifically, the flatness of the bonding surface can be controlled more easily.

The bond portion 40 including AlGe eutectic bonding has a height (Z-direction dimension) of, for example, about 1 to 2 μm, and is smaller than the height of a bond portion formed by glass frit (e.g., about 5 μm at highest). Thus, the bonding surfaces between the device substrate 4 and the lid substrate 5 is to be flatter than when bonded with glass frit. However, in the present embodiment, the seal structure 15 is located on the interlayer insulator layer 24 covering the metal wires 17A and 17B. When the surface 24a of the interlayer insulator layer 24 opposite to its surface adjacent to the first main surface 4a of the device substrate 4 is not flattened, the unevenness on the surface 24a resulting from the interlayer insulator layer 24 covering the metal wires 17A and 17B does not allow the intended flatness on the surface of the exposed portion 15a in the seal structure 15 serving as a bonding surface of the device substrate 4. In the present embodiment, the surface 24a of the interlayer insulator layer 24 opposite to its surface adjacent to the first main surface 4a of the device substrate 4 is flattened to achieve intended flatness on the surface of the exposed portion 15a in the seal structure 15 serving as a bonding surface of the device substrate 4.

When the Al layer 38 and the Ge layer 39 in the metal laminate 37 and the seal structure 15 on the device substrate 4 form AlGe eutectic bonding, Al and Ge liquefy. In the present embodiment, the inner-periphery barrier wall 31 and the outer-periphery barrier wall 32 prevent or reduce spread of Al and Ge, liquefied to form the bond portion 40, over the device substrate 4 beyond the exposed portion 15a in the seal structure 15.

A method for manufacturing the MEMS sensor 1 according to the present embodiment will now be described.

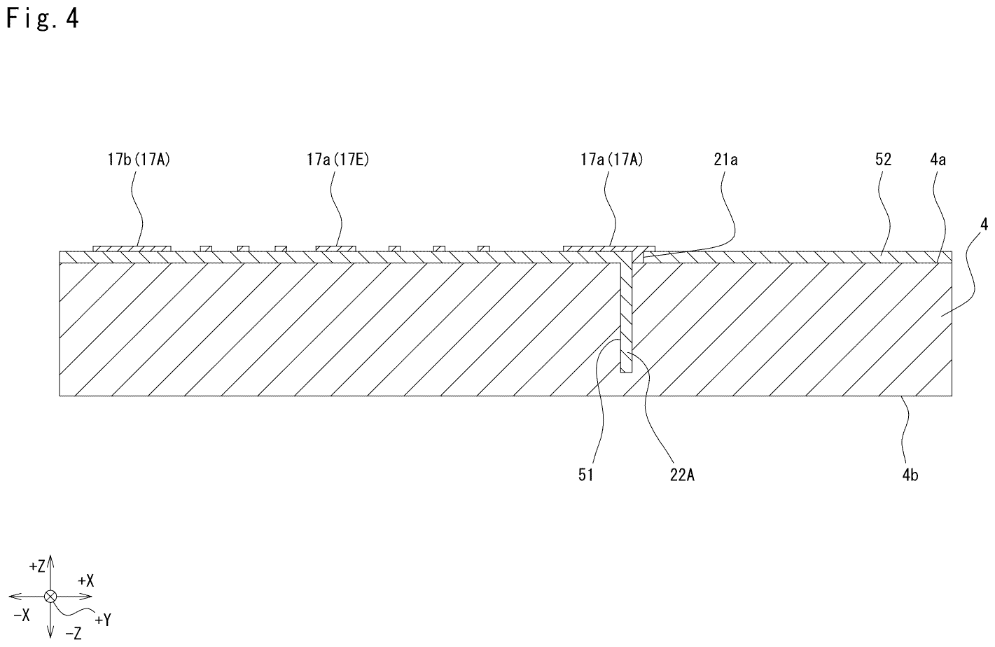

First, a method for manufacturing the device substrate assembly 2 is described with reference to FIGS. 4 to 12.

With reference to FIG. 4, the device substrate 4 as a semiconductor wafer is prepared, and the overall first main surface 4a of the device substrate 4 is thermally oxidized to form a SiO₂ film as a thermal oxidized film on the first main surface 4a of the device substrate 4. The SiO₂ film is then patterned by photolithography and etching to form openings in portions of the SiO₂ film corresponding to the isolation joints 22A to 22D. Subsequently, anisotropic etching is performed using the SiO₂ film as a mask to remove the portions of the first main surface 4a of the device substrate 4 corresponding to the isolation joints 22A to 22D to form trenches 51.

After the trenches 51 are formed, the SiO₂ film formed on the first main surface 4a of the device substrate 4 is removed by etching. The overall first main surface 4a of the device substrate 4 including the inner surfaces of the trenches 51 is then thermally oxidized to form the isolation joints 22A to 22D as a SiO₂ film with which the trenches 51 are filled and to form a first oxide film 52 from SiO₂ covering an overall first main surface 10a of a first substrate 10. The first contact holes 21a are further formed in the first oxide film 52 by photolithography and etching. An AlSi film is then formed on the first oxide film 52 and patterned to form the metal wires 17A to 17E. A part of each of the metal wires 17A to 17E enters the corresponding first contact hole 21a to be electrically connected to the device substrate 4 on the first main surface 4a.

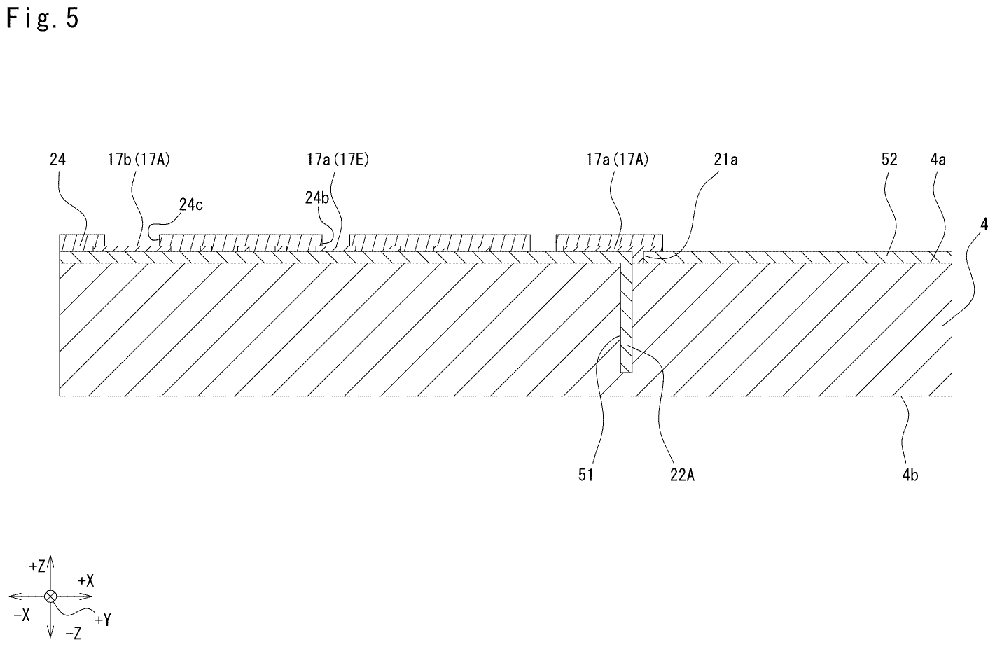

With reference to FIG. 5, a TEOS film to be the interlayer insulator layer 24 is formed by chemical vapor deposition (CVD) to cover the metal wires 17A to 17E. The surface of the TEOS film is flattened by chemical mechanical polishing (CMP) or by performing etch-back on the overall surface. After the flattening, photolithography and etching are performed on the TEOS film to remove areas of the TEOS film in which the MEMS electrodes 6 are to be formed and to form the insulator layer 23 that covers the first contacts 17a in the metal wires 17A to 17E and the interlayer insulator film 24 having the flattened surface 24a opposite to the surface adjacent to the first main surface 4a. The second contact hole 24b and the third contact holes 24c are also formed in the interlayer insulator film 24.

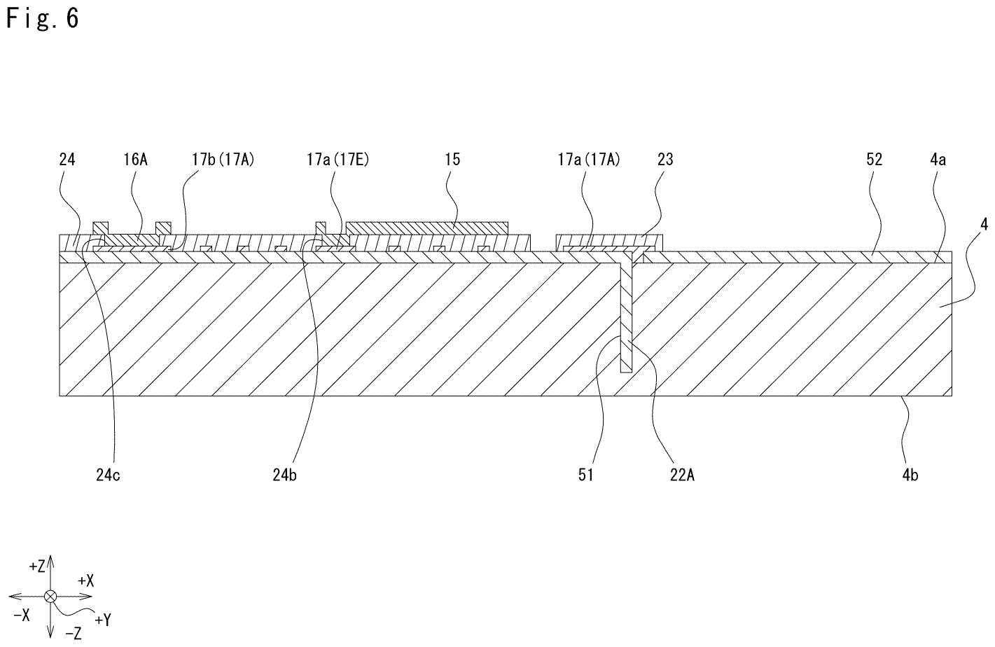

With reference to FIG. 6, a Ti/TiN laminate film to be the diffusion barrier layer 25 and the first adhesion layer 26 (refer to FIG. 3) is formed on the overall surface of the interlayer insulator layer 24. More specifically, a Ti film is formed on the overall surface of the interlayer insulator layer 24, and a TiN film is formed on the Ti film. An AlCu film to be the seal structure 15 and the electrode pads 16A to 16E is then formed on the overall surface of the Ti/TiN laminate film. The Ti/TiN film and the AlCu film are then patterned by photolithography and etching. Thus, the seal structure 15, the electrode pads 16A to 16E, the diffusion barrier layer 25, and the first adhesion layer 26 are formed.

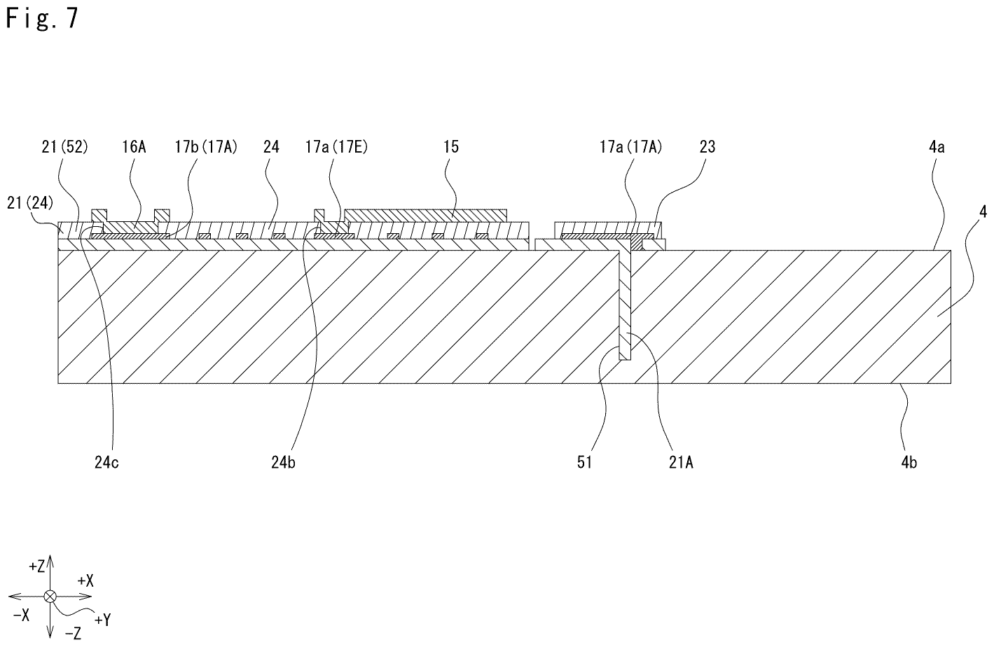

With reference to FIG. 7, the areas of the first oxide film 52 in which the MEMS electrodes 6 are formed are removed by photolithography and etching to expose the first main surface 4a of the device substrate 4 in these areas. The first oxide film 24 left unremoved is the main insulator film 21.

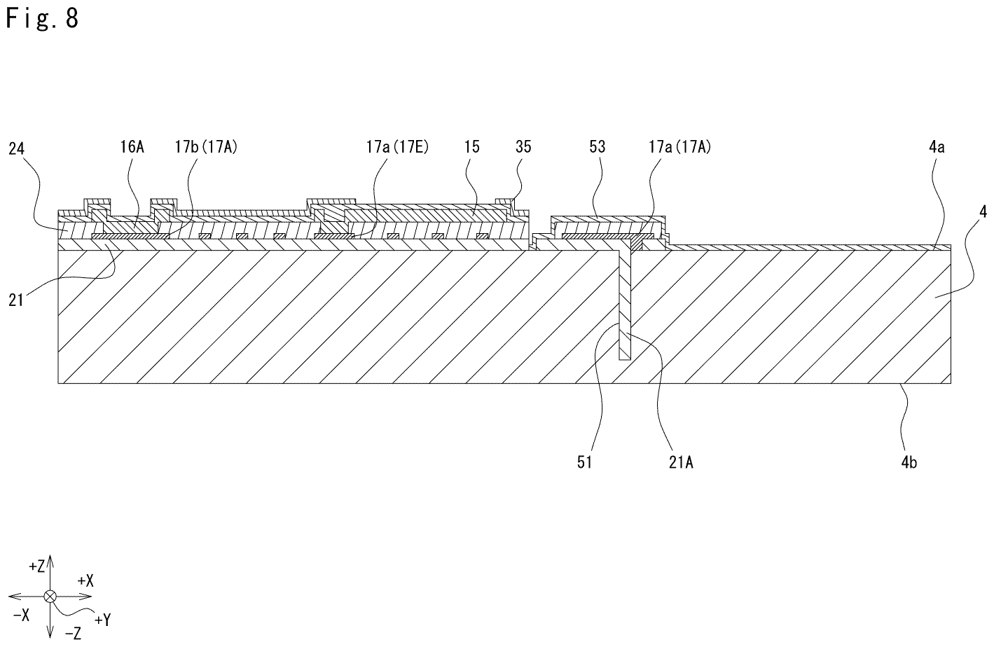

With reference to FIG. 8, an USG film 53 to be the inner-periphery control wall 31, the outer-periphery control wall 32, the barrier 33, and the intermediate structure 34 is formed on the overall first main surface 4a of the device substrate 4. An Al film to be the barrier film 35 is formed on the USG film 53. The Al film is then patterned by photolithography and etching to remove an area of the Al film in which the sensor device 2 is formed, a portion of the Al film to be the seal structure 15, and portions of the Al film to be the electrode pads 16A to 16E. Thus, the barrier film 35 is formed.

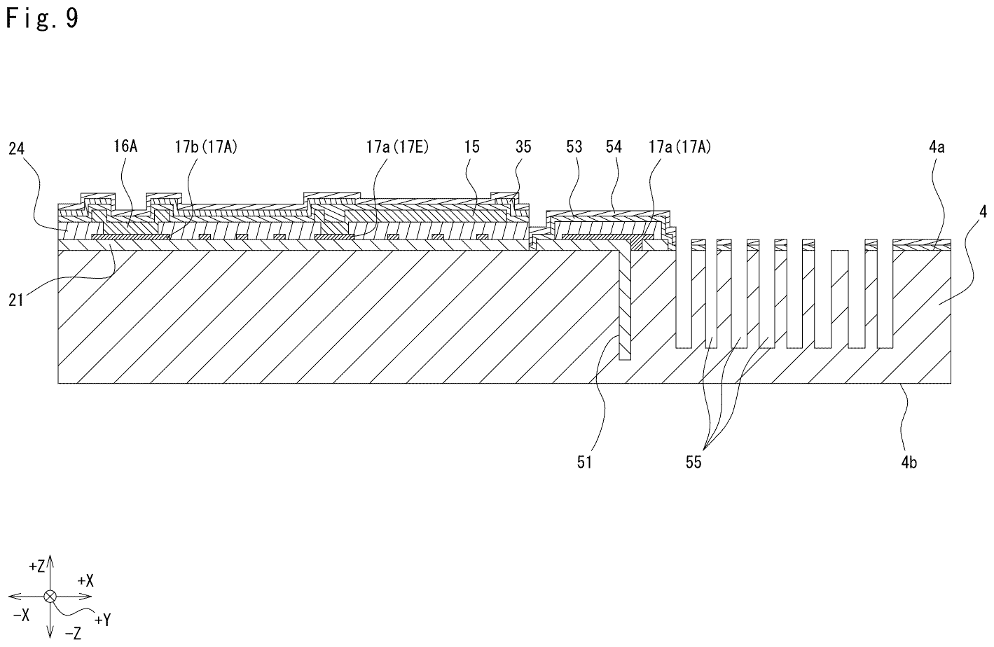

With reference to FIG. 9, a second oxide film 54 formed from SiO₂ is deposited by CVD on the overall first main surface 4a of the device substrate 4. A resist having openings corresponding to the shapes of the movable electrode 13 and the fixed electrode 14 in the sensor device 2 is formed on the second oxide film 54, and anisotropic etching is performed using this resist as a mask. This forms trenches 55 having shapes corresponding to the shapes of the movable electrode 13 and the fixed electrode 14, particularly, the shapes of the electrodes 13c and 14c.

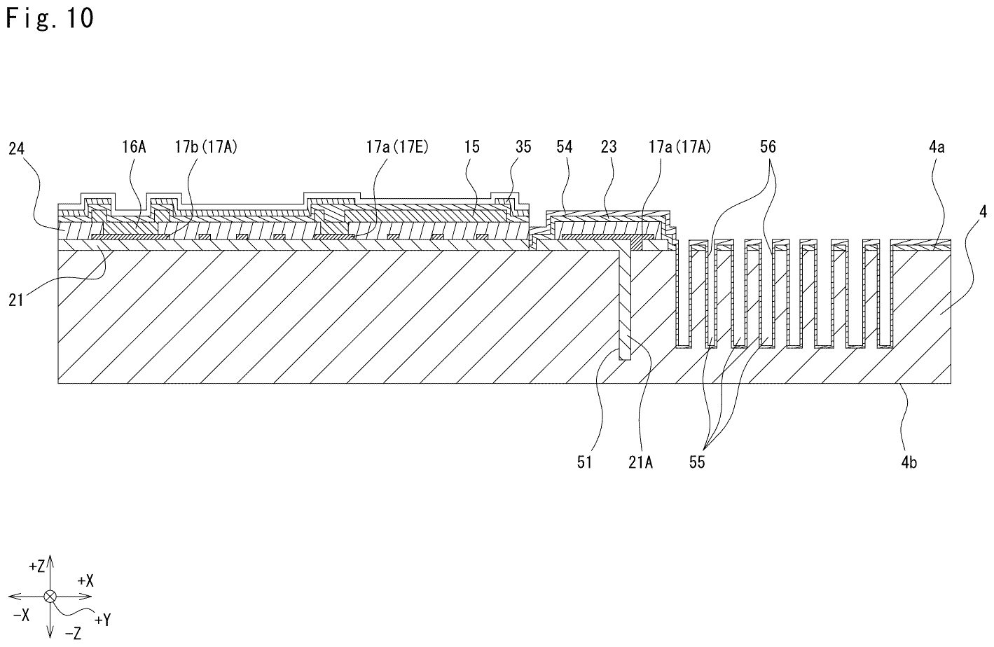

With reference to FIG. 10, a protective film 56 formed from SiO₂ is deposited by CVD on the overall first main surface 4a of the device substrate 4 and on the inner surfaces of the trenches 55. Subsequently, the portion of the protective film 56 except for portions on the inner surfaces of the trenches 55 is removed by etch-back. Thus, the protective film 56 is left on the inner surfaces (side surfaces and bottom surfaces) of the trenches 57 alone.

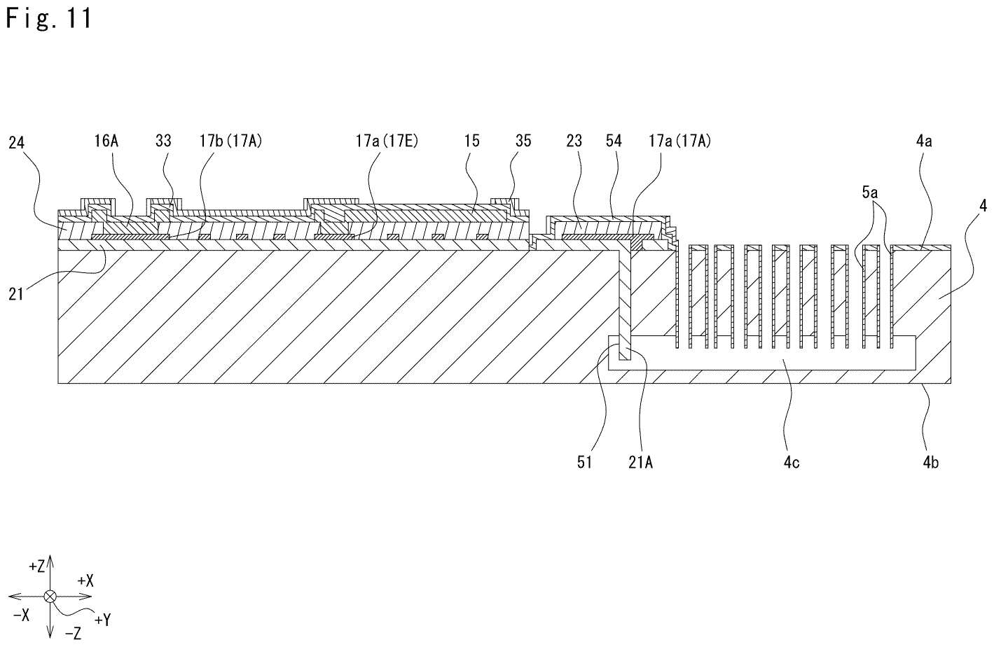

With reference to FIG. 11, anisotropic etching is performed using the second oxide film 54 as a mask to further etch the bottom surfaces of the trenches 55 downward to expose the device substrate 4 at bottom portions of the trenches 54. The anisotropic etching is followed by isotropic etching to form the hollows 4c.

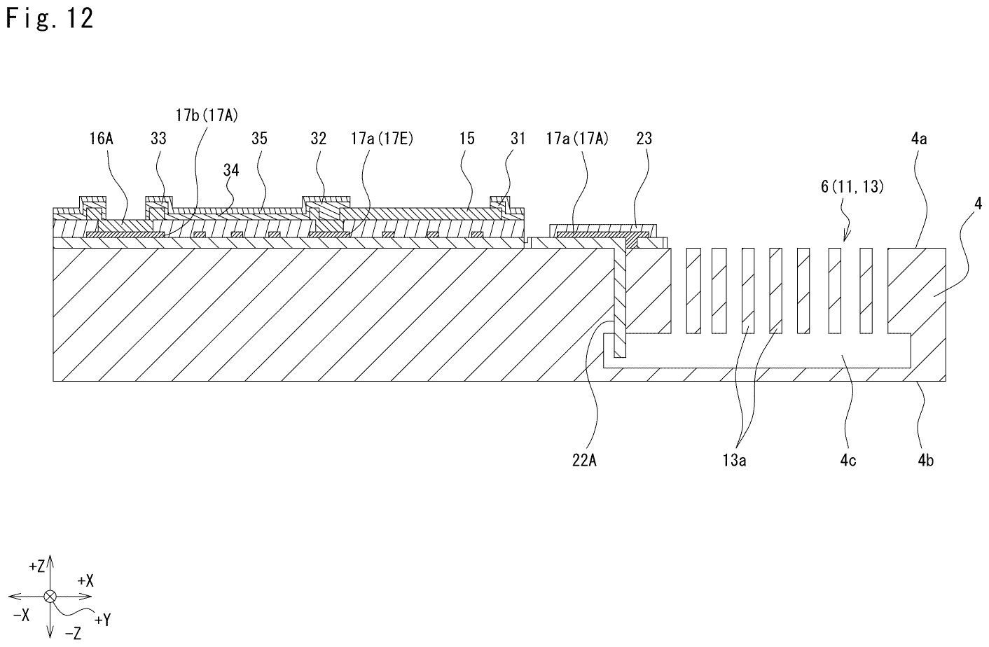

With reference to FIG. 12 finally, the protective film 56 on the side walls of the trenches 55, the second oxide film 54 covering the exposed portion 15a in the seal structure 15, and the second oxide film 54 covering the electrode pads 16A to 16E are removed by hydrofluoric acid vapor etching. This completes the sensor device 2, and also forms the inner-periphery control wall 31, the outer-periphery control wall 32, the barrier 33, and the intermediate structure 34. The barrier film 35 covering the surfaces of the inner-periphery control wall 31, the outer-periphery control wall 32, the barrier 33, and the intermediate structure 34 is formed from Al, and is resistant to hydrofluoric acid vapor etching. Thus, the inner-periphery control wall 31, the outer-periphery control wall 32, the barrier 33, and the intermediate structure 34 are unetched by hydrofluoric acid vapor etching. More specifically, the barrier film 35 functions as a mask that protects the inner-periphery control wall 31, the outer-periphery control wall 32, the barrier 33, and the intermediate structure 34.

The above processes complete the manufacture of the device substrate assembly 2.

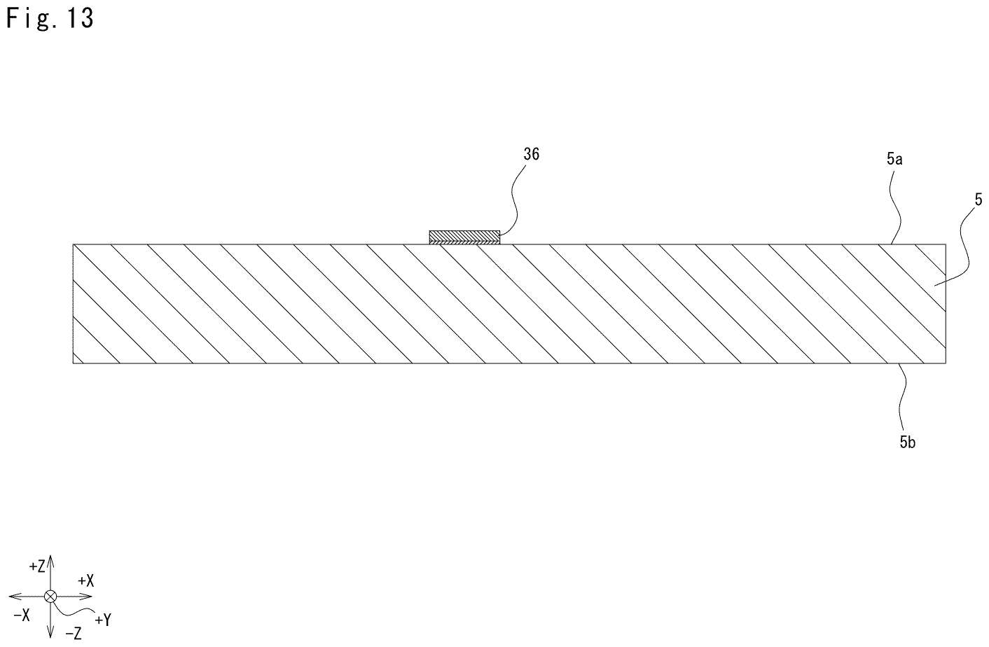

With reference to FIGS. 13 to 16, a method for manufacturing the device substrate assembly 2 is described.

With reference to FIG. 13, the lid substrate 5 as a semiconductor wafer is prepared, and a Ti/TiN film to be the second adhesion layer 36 is formed on the third main surface 5a of the lid substrate 5. More specifically, a Ti film is formed on the third main surface 5a, and a TiN film is formed on the Ti film. Subsequently, the Ti/TiN film is patterned by photolithography and etching. The second adhesion layer 36 is thus formed.

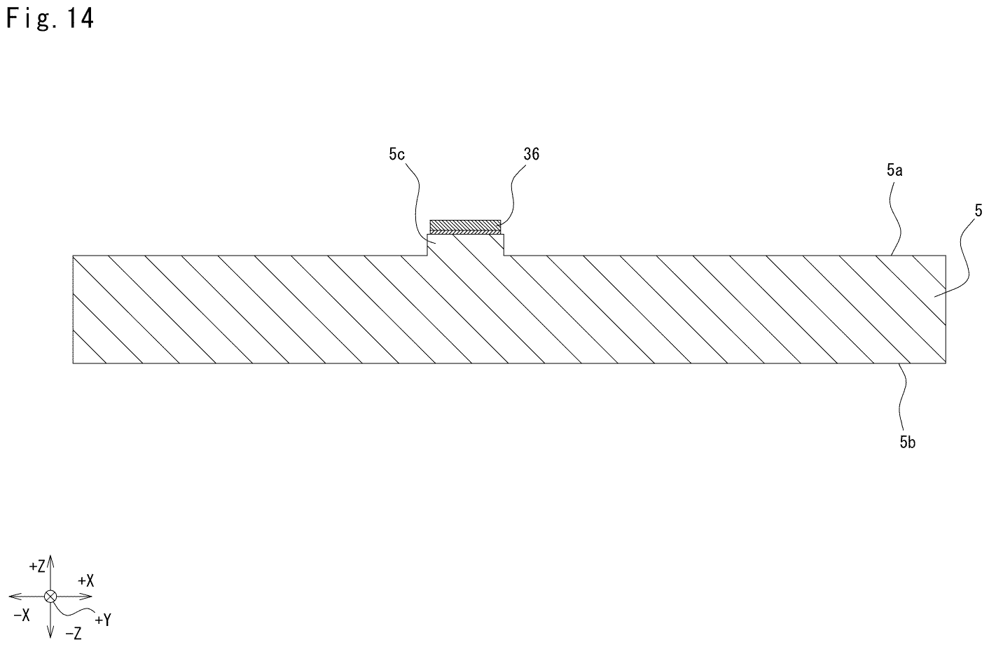

With reference to FIG. 14, the third main surface 5a of the lid substrate 5 is patterned by photolithography and etching to selectively leave a portion on which the second adhesion layer 36 is formed. Thus, the protrusion 5c is formed.

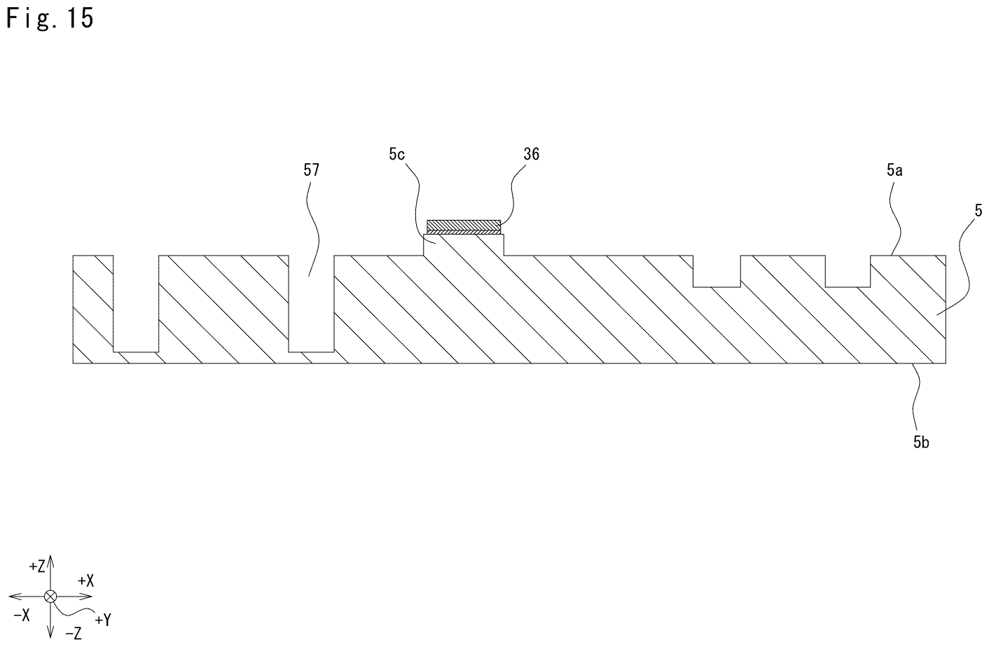

With reference to FIG. 15, a recess 57 is formed on the third main surface 5a of the lid substrate 5 by dicing. The lid substrate 5 is to be cut at the recess 57 during singulation performed after the device substrate 4 and the lid substrate 5 are bonded (described later). The recess 57 may also be formed by photolithography and etching.

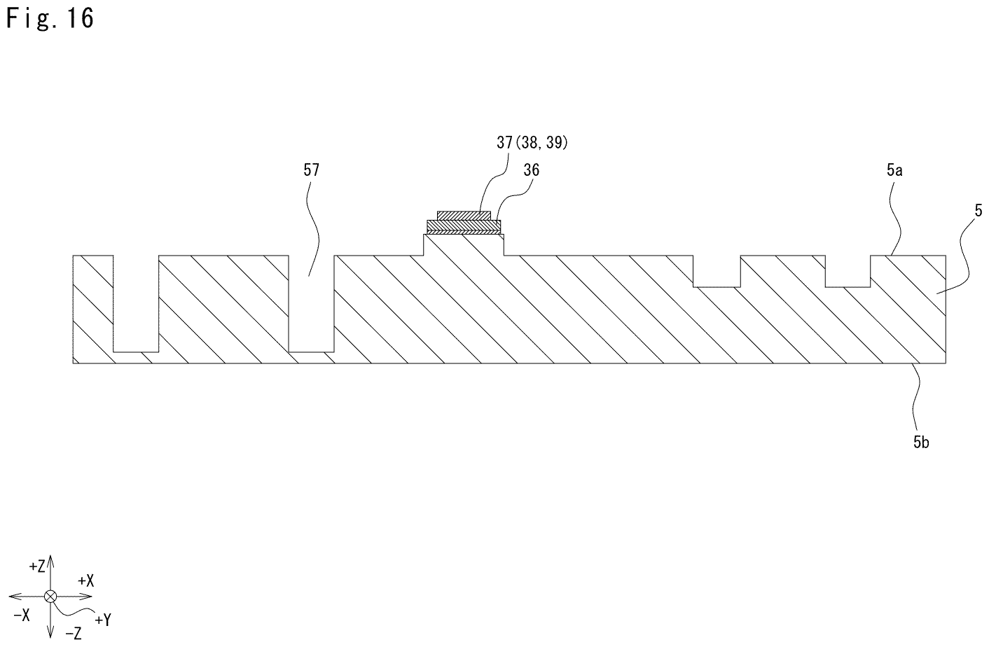

With reference to FIG. 16, an AlGe film to be the metal laminate 37 is formed on the overall third main surface 5a of the lid substrate 5. More specifically, an Al film is formed on the overall third main surface 5a of the lid substrate 5 including the second adhesion layer 36, and a Ge film is formed on the Al film. Subsequently, the AlGe film is patterned by photolithography and etching to selectively leave a portion formed on the second adhesion layer 36. This forms the metal laminate 37.

The above processes complete the manufacture of the lid substrate assembly 2.

With reference to FIGS. 2 and 3, to bond the device substrate assembly 2 and the lid substrate assembly 3, the first main surface 4a of the device substrate 4 facing upward and the third main surface 5a of the lid substrate 5 facing downward are arranged to face each other. The metal laminate 37 in the lid substrate 5 pressed against the seal structure 15 in the device substrate 4 is heated to about 440 to 450° C. This heating liquefies Al and Ge in the metal laminate 37 and Al in the seal structure 15 to form the bond portion 40 including AlGe eutectic bonding.

The inner-periphery control wall 31 and the outer-periphery control wall 32 block outflow of the liquefied Al and Ge from the seal structure 15. More specifically, the inner-periphery control wall 31 and the outer-periphery control wall 32 prevent or reduce spread of the liquefied Al and Ge over the device substrate 4.

The diffusion barrier layer 25 located between the seal structure 15 and the interlayer insulator layer 24 prevents or reduces diffusion of eutectic reaction of Al and Ge to form the bond portion 40 to the metal wire layers.

Eutectic bonding between two metals may be other than AlGe eutectic bonding.

One or more embodiments of the disclosure will be described below briefly.

A micro-electromechanical systems sensor according to one aspect of the disclosure includes a first substrate assembly, a second substrate assembly, and a bond portion. The first substrate assembly includes a first semiconductor substrate having a first main surface and a second main surface opposite to the first main surface and having a hollow on the first main surface, a micro-electromechanical systems electrode located in the hollow, a metal wire layer located on the first main surface of the first semiconductor substrate and electrically connected to the micro-electromechanical systems electrode, an interlayer insulator layer covering the metal wire layer, and a metal structure located on the interlayer insulator film layer, including an exposed portion, and including a metal material including a first metal. The second substrate assembly includes a second semiconductor substrate having a third main surface facing the first main surface and a fourth main surface opposite to the third main surface. The second semiconductor substrate faces the first semiconductor substrate and covers the micro-electromechanical systems electrode. The bond portion is a bond portion in which the metal structure and a metal laminate are eutectically bonded. The bond portion bonds the first semiconductor substrate and the second semiconductor substrate. The metal laminate is located on the third main surface and facing the exposed portion in the metal structure. The metal laminate includes the first metal and a second metal different from the first metal.

The bond portion bonding the first semiconductor substrate (device substrate) and the second semiconductor substrate (lid substrate) includes eutectic bonding. The bond portion including eutectic bonding is formed from a eutectic metal that is a ductile material, and cracks less easily. The bonding width can thus be reduced, with the sealing performance retained for the MEMS electrodes. The MSMS sensor thus achieves size reduction. The bond portion including eutectic bonding is formed by, for example, lithography or etching instead of printing, and thus can reduce particles. When the bond portion including eutectic bonding is formed, the bonding surfaces between the first semiconductor substrate (device substrate) and the second semiconductor substrate (lid substrate) can have less flatness being intended than when the bond portion is formed by diffusion bonding. More specifically, the flatness of the bonding surface can be controlled more easily

The first metal may be Al, and the second metal may be Ge.

The interlayer insulator film layer may have a flattened surface opposite to a surface of the interlayer insulator film layer adjacent to the first main surface.

The surface of the interlayer insulator film layer opposite to its surface adjacent to the first main surface is flattened to reduce or remove height difference resulting from the metal wire layers. Thus, the bonding surface of the metal structure in the first semiconductor substrate (device substrate) bonded with the metal laminate in the second semiconductor substrate (lid substrate) can have intended flatness.

The micro-electromechanical systems sensor may include a diffusion barrier layer between the metal structure and the interlayer insulator layer to reduce diffusion of the first and second metals to the metal wire layer.

The diffusion barrier layer prevents or reduces diffusion of eutectic reaction between the first metal and the second metal used to form the bond portion to the metal wire layers.

The diffusion barrier layer may be a Ti/TiN laminate film.

The micro-electromechanical systems sensor may include a control wall including an oxide film. The control wall may surround a periphery of the metal structure and define the exposed portion.

The control wall prevents or reduces spread of the first metal and the second metal, liquefied to form the bond portion, over the first semiconductor substrate (device substrate) beyond the exposed portion.

The control wall may be formed from undoped silicate glass.

The micro-electromechanical systems sensor may further include a barrier film located on a surface of the control wall. The barrier film may be formed from a material resistant to etching for the control wall.

The barrier wall on the surface of the control wall prevents etching of the control wall when an oxide film for forming the control wall is being etched.

The barrier film may be formed from Al or AlO₂.

The metal structure may surround the micro-electromechanical systems electrode, and the bond portion may seal the micro-electromechanical systems electrode.

A method for manufacturing a micro-electromechanical systems sensor according to another aspect of the disclosure includes preparing a first semiconductor substrate having a first main surface and a second main surface opposite to the first main surface, forming a metal wire layer on the first main surface of the first semiconductor substrate to allow electrical connection to a micro-electromechanical systems electrode, forming an interlayer insulator film layer covering the metal wire layer, flattening a surface of the interlayer insulator film layer, forming a metal structure including a first metal on the surface of the interlayer insulator film layer, preparing a second semiconductor substrate having a third main surface and a fourth main surface opposite to the third main surface, forming, on the third main surface of the second semiconductor substrate, a metal laminate including the first metal and a second metal different from the first metal, placing the third main surface of the second semiconductor substrate to face the first main surface of the first semiconductor substrate and placing the metal laminate into contact with the metal structure, and forming a bond portion bonding the first semiconductor substrate and the second semiconductor substrate by eutectic bonding between the metal laminate and the metal structure.

### EXPLANATION OF REFERENCES

1: MEMS sensor
2: device substrate assembly (first substrate assembly)
3: lid substrate assembly (second substrate assembly)
4: device substrate (first semiconductor substrate)
4a: first main surface
4b: second main surface
4c: hollow
4d: bottom wall
4e: side wall
5: lid substrate (second semiconductor substrate)
5a: third main surface
5b: fourth main surface
5c: protrusion
6: MEMS electrode
8: pad portion
11: X-axis sensor device
12: Y-axis sensor device
13: movable electrode
13a: connector
13b: base
13c: electrode
13d: spring
14: fixed electrode
14a: connector
14b: base
14c: electrode
15: seal structure (metal structure)
15a: exposed portion
15b: inner periphery
15c: outer periphery
16A, 16B, 16C, 16D, 16E: electrode pad
17A, 17B, 17C, 17D, 17E: metal wire
17a: first contact
17b: second contact
21: main insulator film
21a: first contact hole
22A, 22B, 22C, 22D: isolation joint
23: insulator layer
24: interlayer insulator layer
24a: surface
24b: second contact hole
24c: third contact hole
25: diffusion barrier layer
26: first adhesion layer
31: inner-periphery control wall
32: outer-periphery control wall
33: barrier
34: intermediate structure
35: barrier film
36: second adhesion layer
37: metal laminate
38: Al layer
39: Ge layer
40: bond portion
51, 55: trench
52: first oxide film
53: USG film
54: second oxide film
56: protective film
57: recess

What is claimed is:

1. A micro-electromechanical systems sensor, comprising:
a first substrate assembly including
a first semiconductor substrate having a first main surface and a second main surface opposite to the first main surface, and having a hollow on the first main surface,
a micro-electromechanical systems electrode located in the hollow,
a metal wire layer located on the first main surface of the first semiconductor substrate and electrically connected to the micro-electromechanical systems electrode,
an interlayer insulator layer covering the metal wire layer, and
a metal structure located on the interlayer insulator film layer, including an exposed portion, and comprising a metal material including a first metal;
a second substrate assembly including
a second semiconductor substrate having a third main surface facing the first main surface and a fourth main surface opposite to the third main surface, the second semiconductor substrate facing the first semiconductor substrate and covering the micro-electromechanical systems electrode; and
a bond portion in which the metal structure and a metal laminate are eutectically bonded, the bond portion bonding the first semiconductor substrate and the second semiconductor substrate, the metal laminate being located on the third main surface and facing the exposed portion in the metal structure, the metal laminate comprising the first metal and a second metal different from the first metal.

2. The micro-electromechanical systems sensor according to claim 1, wherein
the first metal is Al, and
the second metal is Ge.

3. The micro-electromechanical systems sensor according to claim 1, wherein
the interlayer insulator film layer has a flattened surface opposite to a surface of the interlayer insulator film layer adjacent to the first main surface.

4. The micro-electromechanical systems sensor according to claim 2, wherein
the interlayer insulator film layer has a flattened surface opposite to a surface of the interlayer insulator film layer adjacent to the first main surface.

5. The micro-electromechanical systems sensor according to claim 1, further comprising:
a diffusion barrier layer between the metal structure and the interlayer insulator layer to reduce diffusion of the first metal and the second metal to the metal wire layer.

6. The micro-electromechanical systems sensor according to claim 2, further comprising:
a diffusion barrier layer between the metal structure and the interlayer insulator layer to reduce diffusion of the first metal and the second metal to the metal wire layer.

7. The micro-electromechanical systems sensor according to claim 3, further comprising:
a diffusion barrier layer between the metal structure and the interlayer insulator layer to reduce diffusion of the first metal and the second metal to the metal wire layer.

8. The micro-electromechanical systems sensor according to claim 4, further comprising:
a diffusion barrier layer between the metal structure and the interlayer insulator layer to reduce diffusion of the first metal and the second metal to the metal wire layer.

9. The micro-electromechanical systems sensor according to claim 5, wherein
the diffusion barrier layer is a Ti/TiN laminate film.

10. The micro-electromechanical systems sensor according to claim 6, wherein
the diffusion barrier layer is a Ti/TiN laminate film.

11. The micro-electromechanical systems sensor according to claim 7, wherein
the diffusion barrier layer is a Ti/TiN laminate film.

12. The micro-electromechanical systems sensor according to claim 8, wherein
the diffusion barrier layer is a Ti/TiN laminate film.

13. The micro-electromechanical systems sensor according to claim 1, further comprising:
a control wall including an oxide film, the control wall surrounding a periphery of the metal structure and defining the exposed portion.

14. The micro-electromechanical systems sensor according to claim 13, wherein
the control wall comprises undoped silicate glass.

15. The micro-electromechanical systems sensor according to claim 13, further comprising:
a barrier film located on a surface of the control wall, the barrier film comprising a material resistant to etching for the control wall.

16. The micro-electromechanical systems sensor according to claim 15, wherein
the barrier film comprises Al or AlO₂.

17. The micro-electromechanical systems sensor according to claim 1, wherein
the metal structure surrounds the micro-electromechanical systems electrode, and
the bond portion seals the micro-electromechanical systems electrode.

18. A method for manufacturing a micro-electromechanical systems sensor, the method comprising:
preparing a first semiconductor substrate having a first main surface and a second main surface opposite to the first main surface;
forming a metal wire layer on the first main surface of the first semiconductor substrate to allow electrical connection to a micro-electromechanical systems electrode;
forming an interlayer insulator film layer covering the metal wire layer;
flattening a surface of the interlayer insulator film layer;
forming a metal structure comprising a first metal on the surface of the interlayer insulator film layer;
preparing a second semiconductor substrate having a third main surface and a fourth main surface opposite to the third main surface;
forming, on the third main surface of the second semiconductor substrate, a metal laminate comprising the first metal and a second metal different from the first metal;
placing the third main surface of the second semiconductor substrate to face the first main surface of the first semiconductor substrate and placing the metal laminate into contact with the metal structure; and
forming a bond portion bonding the first semiconductor substrate and the second semiconductor substrate by eutectic bonding between the metal laminate and the metal structure.
